(19) United States
(12) Patent Application Publication
(10) Pub. No.: US 2021/0384016 A1
(43) Pub. Date: Dec. 9, 2021

(54) PLASMA SOURCE AND METHOD FOR PREPARING AND COATING SURFACES USING ATMOSPHERIC PLASMA PRESSURE WAVES

(71) Applicant: Atmospheric Plasma Solutions, Inc., Cary, NC (US)

(72) Inventor: Peter Joseph Yancey, Cary, NC (US)

(21) Appl. No.: 17/288,070

(22) PCT Filed: Oct. 24, 2019
(86) PCT No.: PCT/US2019/057830

§ 371 Date: Apr. 23, 2021

Related U.S. Application Data
(60) Provisional application No. 62/749,833, filed on Oct. 24, 2018.

(51) Int. Cl. H01J 37/32; C23C 4/134; C23C 4/04

(52) U.S. Cl. CPC H01J 37/32862; H01J 37/32825; H01J 2237/332; C23C 4/134; C23C 4/04; H01J 37/3244

(57) ABSTRACT

A method for cleaning a surface of a substrate with an atmospheric pressure plasma process in which a plasma is generated at atmospheric pressure. The plasma has an energetic species reactive with one or more components of an undesirable material on the substrate. In this method, the plasma flows from a nozzle exit as a plasma plume exiting into an ambient environment, and the surface of the substrate is exposed to the energetic species in the plasma plume, thereby producing an activated surface capable of adhering on contact a coating material to the activated surface.

### CROSS REFERENCE TO RELATED APPLICATIONS

This application is related to and claims priority to U.S. Provisional Patent Application Ser. No. 62/749,833, filed Oct. 24, 2018, titled “METHOD OF PROMOTING ADHESION OF COLD-SPRAY COATINGS ON VARIOUS SURFACES,” the content of which is incorporated by reference herein in its entirety. This application is related to U.S. Ser. No. 12/702,039, filed Feb. 8, 2010, titled “PLASMA SOURCE AND METHOD FOR REMOVING MATERIALS FROM SUBSTRATES UTILIZING PRESSURE WAVES,” the content of which is incorporated by reference herein in its entirety. This application is related to U.S. Provisional Patent Application Ser. No. 61/150,795, filed Feb. 8, 2009, titled “COATING REMOVAL DEVICE AND METHODS,” the content of which is incorporated by reference herein in its entirety.

### TECHNICAL FIELD

The present invention generally relates to the removal of materials from substrates utilizing atmospheric pressure plasma pressure waves.

### BACKGROUND

Atmospheric pressure (AP) plasma may be utilized to remove a coating of material (e.g., a layer, film, paint, etc.) from the surface of a substrate. The source of the AP plasma may be a device configured to discharge an AP plasma plume from a nozzle. The device may positioned at some specified distance between the nozzle and the surface of the coating, and oriented so as to direct the AP plasma plume toward the coating. While the AP plasma plume is active, the device may be moved across the coating along an appropriate path to effect removal of the coating or a desired portion thereof.

The coating may include a combination of components, some of which are readily removable by a conventional AP plasma (reactive or plasma-responsive components) and some of which are not (non-reactive or non-responsive components). An example is a coating or paint that includes organic or polymeric components that are reactive to one or more energetic species of the AP plasma, but also includes inorganic pigments and fillers that are generally not responsive to the AP plasma. As a conventional AP plasma is applied to such a coating, loosely bonded inorganic components begin to build up and serve as an etch-resistant layer or diffusion barrier to the activated chemical species of the AP plasma plume. Consequently, the material removal rate and hence the effectiveness of the conventional AP plasma device rapidly become diminished (e.g., within milliseconds). Prior to the filing of the '795 provisional application, the solution was to cease application of the AP plasma plume, mechanically abrade or brush the surface with a brush, rough cloth, rough sponge, or another type of dry wipe in an attempt to sweep away the build-up, and then resume application of the AP plasma plume to reach additional layers of coating requiring removal, and often make additional passes over areas previously obstructed by the build-up. Depending on the thickness and composition of the material being removed from the underlying substrate, these iterations need to be repeated a number of times until the material is completely removed from the substrate.

The '795 provisional application eliminated this problem by providing plasma pressure waves which removed various types of materials from substrates without need to stop the process and perform and intervening cleaning.

U.S. Pat. No. 8,263,178 (the entire contents of which are incorporated herein by reference) describes a process for the in-flight surface treatment of powders using a dielectric barrier discharge torch operating at atmospheric pressures or soft vacuum conditions to prepare the surfaces of the powders. In the '178 patent, the surface treated powders are collected for later use.

U.S. Pat. No. 5,770,273 (the entire contents of which are incorporated herein by reference) describes a durable coating plasma based process which provides improved adhesive bond strength between the coating and its substrate. Yet, in achieving this improvement, the '273 patent describes that oxidizing species increase the electrochemical corrosion potential (ECP) of metals. Electrochemical corrosion is caused by a flow of electrons from anodic to cathodic areas on metallic surfaces. The ECP is a measure of the kinetic tendency for corrosion phenomena to occur, and is a fundamental parameter in determining the rate of stress control cracking.

### SUMMARY OF THE INVENTION

In one embodiment of the invention, there is provided a method for cleaning a surface of a substrate with atmospheric pressure plasma pressure waves in which a plasma is generated at atmospheric pressure. The plasma has an energetic species reactive with one or more components of an undesirable material on the substrate. In this method, the plasma flows from a nozzle exit as a plasma plume exiting into an ambient environment, and the surface of the substrate is exposed to the energetic species in the plasma plume, thereby producing an activated surface capable of adhering on contact with a coating material to the activated surface.

In one embodiment of the invention, there is provided an atmospheric pressure plasma source having at least one plasma-generating chamber configured to generate a first atmospheric pressure plasma, a plasma outlet communicating with the plasma-generating chamber, a plasma plume extending from the plasma outlet into an ambient environment. The at least one plasma-generating chamber is configured to generate a second atmospheric pressure plasma for preheating a gas stream prior to introduction of solid precursor particles for a cold spray coating.

In one embodiment of the invention, there is provided an atmospheric pressure plasma source having a plasma-generating chamber configured to generate an atmospheric pressure plasma for preheating a plasma-heated gas stream for introduction of precursor particles for a cold spray coating, a particle injector for injection of the precursor particles into the plasma-heated gas stream, and a plasma outlet communicating with the plasma-generating chamber and through which a plasma plume exits in an ambient environment.

It is to be understood that both the foregoing general description of the invention and the following detailed description are exemplary, but are not restrictive of the invention.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1 illustrates an example of utilizing a conventional AP plasma source.

FIG. 2 is a cross-sectional elevation view of a portion of a typical coated structure to which AP plasma may be applied.

FIG. 3 is a cross-sectional elevation view of the coated structure illustrated in FIG. 2 while initially subjected to a conventional plasma.

FIG. 4 is a cross-sectional elevation view of the coated structure illustrated in FIG. 2 while undergoing the conventional plasma treatment after a very brief period of time.

FIG. 5 is a diagram of an example of an AP plasma application system according to implementations disclosed herein.

FIG. 6 illustrates an example of utilizing the AP plasma source illustrated in FIG. 5.

FIG. 7 is a cross-sectional elevation view of the coated structure while being subjected to a shock-wave or pressure-wave assisted plasma plume at a given instance of time.

FIG. 8 is a cross-sectional elevation view of the coated structure illustrated in FIG. 7 at a later instance of time.

FIG. 9 is a lengthwise cross-sectional view of an example of an AP plasma source that may be configured for producing shock waves or pressure waves in the plasma plume as shown in FIG. 1 while injecting particles for cold spray coatings.

FIG. 10 is a cross-sectional view of another example of an AP plasma source, in transverse plane passing through gas inlets.

FIG. 11A is a cross-sectional view of an example of a nozzle that may be configured for producing shock waves or pressure waves in the plasma plume.

FIG. 11B is a cross-sectional view of an example of another nozzle that may be configured for producing shock waves or pressure waves in the plasma plume.

FIG. 12 is a set of shadowgrams of output flows from an AP plasma source at various air pressures and flow rates.

FIG. 13 is a side elevation view of another example of an AP plasma source according to another implementation.

FIG. 14 is a front perspective view of the front portion of the AP plasma source illustrated in FIG. 13.

FIG. 15A is a diagram of an example of an AP plasma application system according to implementations disclosed herein for preheating precursor particles during coextensive plasma cleaning and cold spray coating.

FIG. 15B is a diagram of another example of an AP plasma application system according to implementations disclosed herein for preheating precursor particles during coextensive plasma cleaning and cold spray coating.

FIG. 15C is a diagram of yet another example of an AP plasma application system according to implementations disclosed herein for preheating precursor particles during coextensive plasma cleaning and cold spray coating.

FIG. 16 is a flowchart depicting an exemplary method of this invention for cleaning a surface of a substrate with atmospheric pressure plasma pressure waves prior to application of a coating onto the cleaned surface of the substrate.

FIG. 17 is a flowchart depicting an exemplary method of this invention for coating a surface of a substrate with a cold spray coating.

FIG. 18 is an exemplary computer system for implementing various embodiments of the present invention.

### DETAILED DESCRIPTION

As used herein, the term “plasma” generally refers to a (partially) ionized gas-like mass comprising a mixture of ions, electrons and neutral species. The term “atmospheric pressure,” in the context of “atmospheric pressure plasma,” is not limited to a precise value of pressure corresponding exactly to sea-level conditions. For instance, the value of “atmospheric pressure” is not limited to exactly 1 atm. Instead, “atmospheric pressure” generally encompasses ambient pressure at any geographic location and thus may encompass a range of values less than and/or greater than 1 atm as measured at sea level. Generally, an “atmospheric pressure plasma” is one that may be generated in an open or ambient environment, i.e., without needing to reside in a pressure-controlled chamber or evacuated chamber.

As used herein, a “non-thermal plasma” generally refers to a plasma exhibiting low temperature ions (relative to a “thermal” plasma) and high electron temperatures relative to the temperature of the surrounding gas. A non-thermal plasma is distinguished from a thermal plasma in that a thermal plasma exhibits a higher overall energy density and both high electron temperatures and high ion and neutral temperatures.

As used herein, the term “cleaning” generically refers to the removal of any undesired material desired to be removed from an underlying substrate. The term “undesired material” is used interchangeably with like terms such as residue, layer, film, paint, contamination, etc. which would tend to inhibit adherence of a coating to the substrate.

As used herein, the term “substrate” generically refers to any structure that includes a surface to be cleaned and one which optionally a coating can be applied after the substrate surface is cleaned. The substrate may present a surface having a simple planar or curved geometry or may have a complex or multi-featured topography. The substrate can be a metallic substrate made from a pure metal or common alloys of metal including, but not limited to, aluminum, or copper, or brass, or tin, or steel, or titanium, or tungsten, or other metals. The substrate can also be a glass or a plastic or a polymer or a ceramic or a composite material. In general, the surface the substrate to be cleaned is exposed to reactive species for the purposes of removing any undesired material and terminating the surface in a manner in which a subsequent coating can adhere.

For purposes of the present disclosure, it will be understood that when a layer (or coating, film, region, substrate, component, device, or the like) is referred to as being “on” or “over” another layer, that layer may be directly or actually on (or over) the other layer or, alternatively, intervening layers (e.g., buffer layers, transition layers, interlayers, sacrificial layers, etch-stop layers, masks, electrodes, interconnects, contacts, or the like) may also be present. A layer that is “directly on” another layer means that no intervening layer is present, unless otherwise indicated. It will also be understood that when a layer is referred to as being “on” (or “over”) another layer, that layer may cover the entire surface of the other layer or only a portion of the other layer. It will be further understood that terms such as “formed on” or “disposed on” are not intended to introduce any limitations relating to particular methods of material transport, deposition, fabrication, surface treatment, or physical, chemical, or ionic bonding or interaction.

In one embodiment, this invention involves the use of an atmospheric pressure plasma source to increase the surface energy of a metallic or ceramic surface to increase the bonding of a cold sprayed metallic surface coating thereto the metallic or ceramic surface. In various embodiments, the cold spray coating may be a pure metal, a pure metal alloy, a cermet or a mixture of metal and inorganic particulates. Cold spray can also be used to deposit polymer coatings. In that case, polymer particles are used. Polymers can be applied to metal, ceramic, or other polymer substrates. Cold spray can also be used to deposit metal on plastics. In one embodiment, the atmospheric pressure plasma is used as a bonding adhesion promoter that enhances the adhesion of cold sprayed coating layers. This permits smooth surfaces with little roughness to be coated with a cold spray coating with improved adhesion.

According to some implementations disclosed herein, an AP plasma source is configured for cleaning operations, including for example the removal of residual organics, polymeric coatings, paints, or the like from substrates or structures of any type. The AP plasma source is configured to clean the substrates with minimal transfer of heat to the underlying substrate. The AP plasma source generates one or more plasma plumes or jets that include one or more energetic, chemically reactive species of a type effective for removing a coating composition of interest. Unlike conventional AP plasmas, the plasma plume(s) can additionally exhibit areas of periodically increasing (high) and decreasing (low) plasma density.

Without wishing to be bound by any one particular theory, it is postulated herein that this periodic plasma density contributes to enhanced removal rates observed, and that the plasma plume may be characterized as exhibiting pressure waves or pressure fronts, which in some implementations may be further characterized as shock waves or shock fronts that may be observed as supersonic shock diamonds or Mach disks. When the AP plasma source is operated to apply the plasma plume to a material to be removed, the shock waves (or other type of pressure waves) generated in the plasma plume physically disrupt the loosely adhered build-up on the material. As the plasma plume is scanned across the surface of the material (or, equivalently, when the material is moved relative to the plasma plume), the as-generated shock waves or pressure waves interacts with the loosely adhered residue and the residue is consequently ejected from or blown off the surface. In some embodiments, a supersonic flow velocity of the exit gas without necessarily containing the shock or pressure waves can remove residue from the surface. Accordingly, the AP plasma source effects material removal by way of a dual modality, one being the chemical (e.g., oxidizing) interaction of the activated plasma species of the plasma plume with the coating and the other being a) the physical interaction of the shock wave or pressure wave structures of the plasma plume with residuals on the surface being cleaned or b) the physical interaction of supersonic gas flow with residuals on the surface being cleaned. The AP plasma source and associated methods permit inorganic or other typically unresponsive components to be rapidly broken up or peeled away, thereby continuously revealing fresh new surfaces of the coating for treatment by the activated species of the plasma.

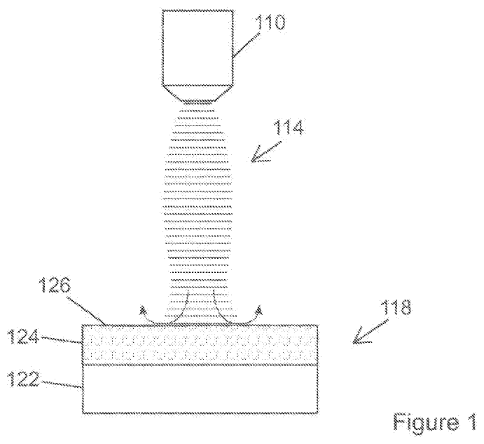

FIG. 1 illustrates an example of utilizing a conventional AP plasma source. Specifically, FIG. 1 illustrates a nozzle 110 of the conventional AP plasma source (not shown) applying a conventional plasma plume 114 to a typical coated structure 118. The coated structure 118 generally includes a substrate 122 and a coating or layer 124 of material desired to be removed cleanly from the substrate 122 without damaging the substrate 122. The conventional plasma plume 114 is shown interacting with a top surface 126 of the coating 124 but is not effective for removing all components of the coating 124. The conventional plasma plume 114 produces no shock wave (or other type of useful pressure wave or supersonic gas flow) and thus applies no appreciable force to the surface 126 effective to disrupt bound inorganic particles or other components unresponsive to the conventional plasma treatment.

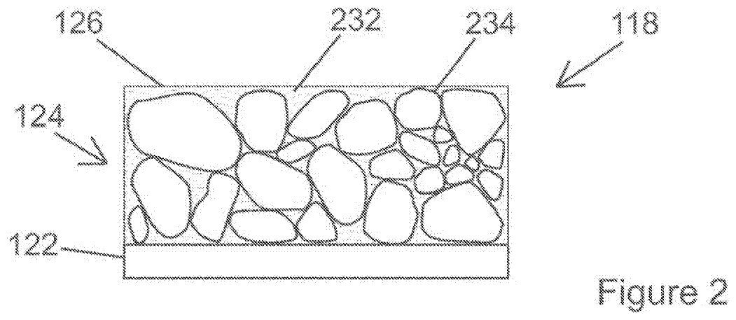

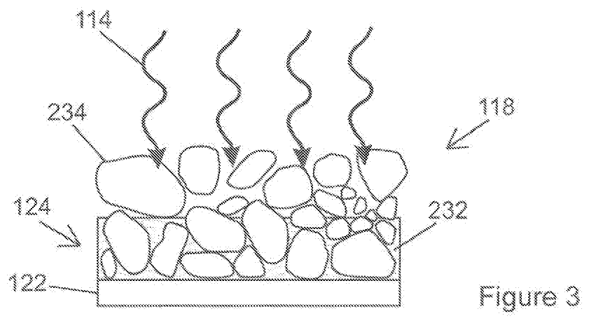

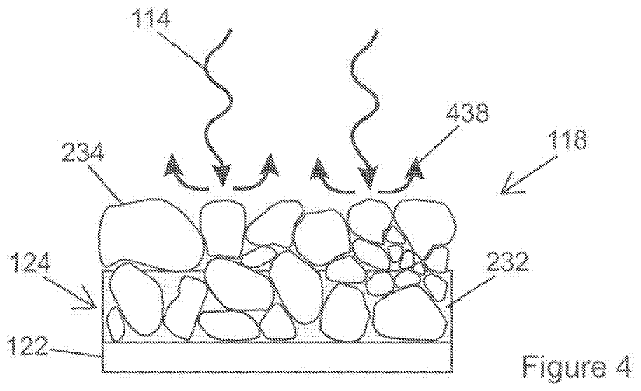

The conventional technique is further illustrated in FIGS. 2, 3 and 4. FIG. 2 is a cross-sectional elevation view of a portion of the coated structure 118 to which AP plasma may be applied. In this example, the coating 124 includes a matrix of organic binder material 232 and inorganic pigment and/or filler particles 234 adhered to the substrate 122. FIG. 3 is a cross-sectional elevation view of the coated structure 118 illustrated in FIG. 2 while initially subjected to the conventional AP plasma 114. The conventional plasma 114 is able to effectively remove some organic material 232, and possibly some material surrounding the inorganic particles 234, but only in the uppermost region of the coating 124 nearest to the plasma source. FIG. 4 is a cross-sectional elevation view of the coated structure 118 illustrated in FIG. 2 while undergoing the conventional plasma treatment after a very brief period of time. In a time period typically less than 1 second (and often only a few milliseconds), the conventional plasma 114 will cease to remove organic binder 232 due to the blocking effect of the inorganic particles 234. The plasma 114 and low-velocity air stream feeding the 114 plasma do not provide sufficient physical force to disrupt the loosely bound inorganic particles 234. As depicted by arrows 438, the plasma 114 and associated ionized species are reflected from the uppermost surface and can do no further work.

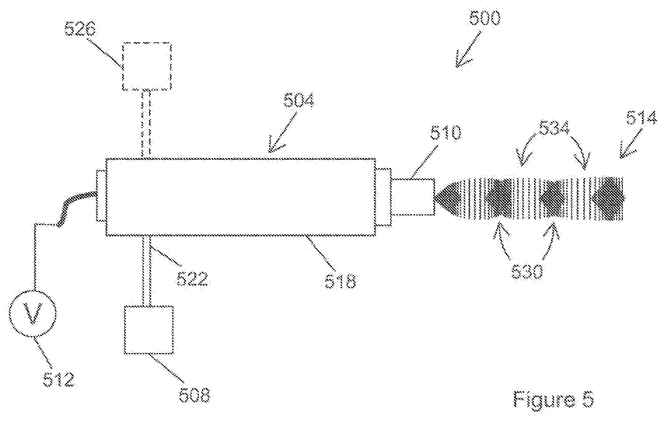

FIG. 5 is a diagram of an example of an AP plasma application system 500 according to implementations disclosed herein. The system 500 generally includes an AP plasma source 504 (or device, applicator, apparatus, instrument, pen, gun, etc.), a plasma-generating gas supply source 508, and a power source 512. The AP plasma source 504 generally includes a main body 518 (or support structure, housing, etc.) which may be configured for manual use (i.e., handheld) or automated use (e.g., attached to a multi-axis robotics system, not shown). For manual operation, a portion of the main body 518 may be utilized as a handle. The AP plasma source 504 further includes a plasma outlet at its distal end from which a plume or jet 514 of AP plasma is generated according to various implementations disclosed herein. In the implementation illustrated in FIG. 5, the plasma outlet is the exit of a nozzle 510 from which the plasma gas exits into an ambient environment. The plasma-generating gas supply source 508 is in fluid communication with a gas inlet 522 of the AP plasma source 504 by any suitable conduit and fittings for supplying a suitable plasma-generating gas to the AP plasma source 504. In one example, the plasma-generating gas is air, in which case the plasma-generating gas supply source 508 may be a source of compressed air or a pump pressurizing ambient air to be supplied to the plasma-generating gas supply source 508. The control and power source 512 is in electrical communication with the AP plasma source 504 by any suitable wiring and connectors for supplying electrical power according to operating parameters suitable for generating and maintaining the type of AP plasma described herein. In FIG. 5, the control and power source 512 includes the electronics and user controls and programs/hardware needed for this purpose.

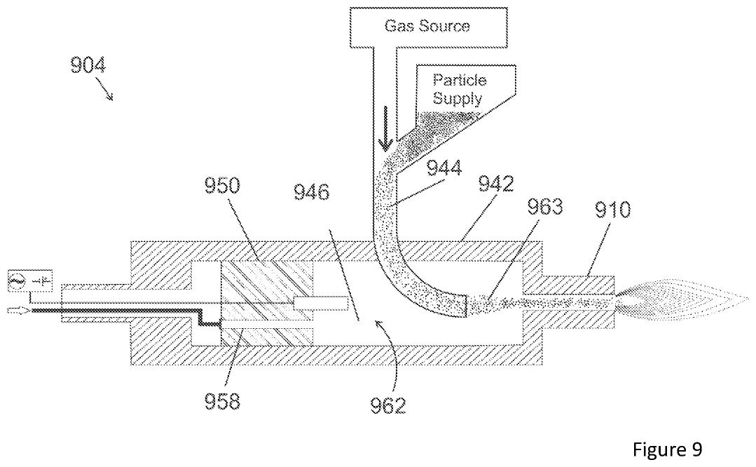

The user controls are configured as necessary to enable the setting and adjustment of various operating parameters of the voltage or current signal fed to the AP plasma source such as, for example, power level, drive voltage amplitude, drive frequency, waveform shape, etc. Electrical signals of AC (e.g., RF), DC, pulsed DC, or arbitrary periodic waveforms with or without an applied DC offset may be utilized to drive the AP plasma as appropriate for a particular application. For simplicity, internal components of the main body 518 of the AP plasma source 504 utilized for receiving the electrical and gas inputs and generating the AP plasma therefrom (e.g., electrodes, gas conduits, etc.) are omitted in FIG. 5. (FIG. 9 shows details of the internal components.) Alternatively, specific mixtures of either noble or non-noble gases may be combined in order to enhance the ionization of secondary, tertiary, or quaternary, species or reactions by a process such as Penning ionization. In the case of an air plasma, the plasma-generating gas supply source 508 may also serve as the source of active species of the AP plasma (e.g., oxygen- and nitrogen- and OH-based species). Alternatively, one or more reactive gas supply sources 526 may also be placed in communication with the AP plasma source 504 for such purposes as enhancing the supply of O₂ or N₂ or for supplying other types of reactive species (e.g., He, Ar, other noble gases, halogens, NH₃, CO₂, various hydrocarbons, etc.) to specifically tailor the chemical species for a given surface cleaning and preparation prior to application of a coating on the cleaned surface.

As further illustrated in FIG. 5, the plasma plume 514 generated by the AP plasma source 504 may be configured as a periodic or alternating series of high plasma density regions 530 and low plasma density regions 534. The high plasma density regions 530 may be considered as including shock fronts (or other types of pressure waves) that propagate in the general direction of the plasma plume 514, i.e., toward a target substrate to be cleaned. Under appropriate operating conditions, the shock fronts may be visually manifested as shock diamonds or Mach disks.

Certain pressure regimes, geometrical configurations, and other operational parameters will give rise to suitable plasma and shock wave generation and control. In one implementation, the nozzle 510 is configured to cause rapid expansion of the gas emanating therefrom. As an example, the nozzle 510 may have a converging or converging-diverging configuration of appropriate dimensions. In this case, the AP plasma generated within the AP plasma source 504 flows from the nozzle exit at supersonic velocity and at a pressure different from (less than or greater than) the ambient pressure outside the nozzle exit. Another example of a nozzle that may be suitable is a non-axially symmetric nozzle such as an aerospike nozzle. In another implementation, the drive frequency and/or power level applied by the power source 512 to the electrical field generating the plasma are controlled so as to modulate the pressure waves (e.g., compression waves) generated in the AP plasma source 504. Pressure waves generated in such manner may be, or be similar to, acoustic shock waves or pressure waves. Similarly, this may be accomplished inductively by generating a time-varying magnetic field to modulate the plasma. In another implementation, the geometry of the AP plasma source 504 (e.g., the volume and the length-to-width ratios of the nozzle 510 and/or upstream plasma-generating chamber) may be selected or adjusted so as to selectively filter or enhance certain frequency modes in the pressure waves of the plasma. This may be analogous to causing acoustic gain or resonance to occur to further enhance the coherency of the shock waves. In another implementation, a piezoelectric material, such as for example various known ceramics or polymers (e.g., barium titanate, lead zirconium titanate, polyvinylidene fluoride, etc.) may be driven by the power source 512 to produce vibrations or oscillations transferred to the as-generated plasma plume. In another implementation, the supply gas pressure to the plasma plume may be modulated in order to create the necessary pressure waves or shockwaves by rapidly actuating a high speed gas valve. For example, a pneumatically actuated valve, electrically actuated valve or piezoelectric valve actuator may be used to modulate the pressure being fed into the AP plasma device.

Generally, operating parameters associated with the AP plasma source 504 are selected so as to produce a stable plasma discharge, with the pressure/shock waves as desired. The operating parameters will depend on the particular application, which may range, for example, from nanoscale etching of micro-fabricated structures or devices (e.g., MEMS devices) to removing paint from metallic surfaces, including the removal of large areas of paint from naval vessels and aircraft carriers. Examples of operating parameters will now be provided with the understanding that the broad teachings herein are not limited by such examples. In the case of generating an air plasma, the rate at which the air is fed to the AP plasma source 504 may range from 1×10⁻⁶ SCCM to 1×10⁶ SCCM. The feed pressure into the AP plasma source 504 may range from 1 Pa to 1×10⁷ Pa. The power level of the electrical field driving the plasma may range from 1×10⁻⁶ W to 1×10⁶ W. The drive frequency of the electrical field may range from DC (0 GHz) to 100 GHz. The separation distance, i.e. the distance from the nozzle exit to the exposed surface of the material to be removed, may range from 1×10⁻⁶ m to 1 m. The scan speed, i.e. the speed at which the AP plasma source 504 is rastered across (over) the surface of the material, may range from 1×10⁻⁴ m/s to 10 m/s. Related to the scan speed and power is the time averaged power density. Also related to the scan speed is the dwell time, i.e., the period of time during which a particular area of the material is exposed to the plasma plume, which may range from 1×10⁻⁹ s to 43×10³ s (1 month). It will be noted that scan speed (or dwell time) effectively characterizes two different techniques for exposing the material to the plasma plume 514, the first being moving the AP plasma source 504 relative to the material (i.e., the material remains in a fixed position) and the second being holding the AP plasma source 504 stationary while moving the coated structure relative to the AP plasma source 504. The foregoing parameters may depend on the composition and thickness of the material to be removed.

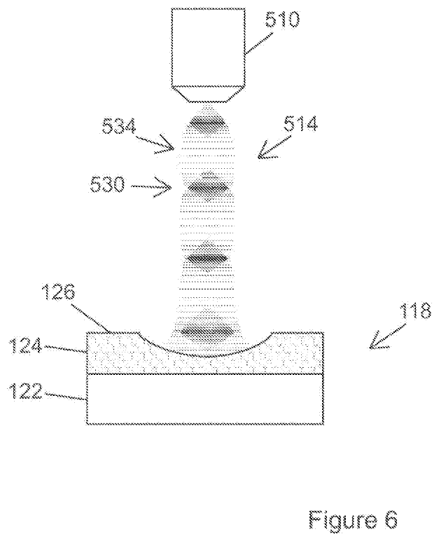

FIG. 6 illustrates an example of utilizing the AP plasma source 504 illustrated in FIG. 5. Specifically, FIG. 6 shows the nozzle 510 applying the shock wave-inclusive plasma plume 514 to the same or similar coated structure 118 described above in conjunction with FIGS. 1-4. Reactive components of the coating material 124 are removed by the active species of the AP plasma. For example, organic compounds may be converted to CO₂ and/or water vapor. In addition, the shock waves 530 (or pressure waves) generated in the AP plasma propagate toward the coated structure 118 and impinge on the uppermost surface 126 of the coating 124. The shock waves 530 disrupt inorganic particles or any other particles which a plasma unassisted by shock waves would fail to remove by sole reliance on active plasma species or incident gas flow pressure. The loosened particles may then be swept away in the gas (e.g., air) stream emanating from the AP plasma source 504 (as part of the plume 514) and may be disposed of by any suitable means (e.g., a vacuum device). Due to the bimodal activity of the shock-assisted plasma plume 514—i.e., a combination of reactive species and shock waves 530 in the plasma—the AP plasma source 504 may be operated on a continuous basis to rapidly penetrate the coated structure 118 of any thickness down to the substrate 122. Unlike conventional plasmas, the plasma plume 514 disclosed herein is not impaired by any accumulation of non-reactive or unresponsive components of the coating 124 and thus its optimized material removal rate may be preserved throughout the removal operation.

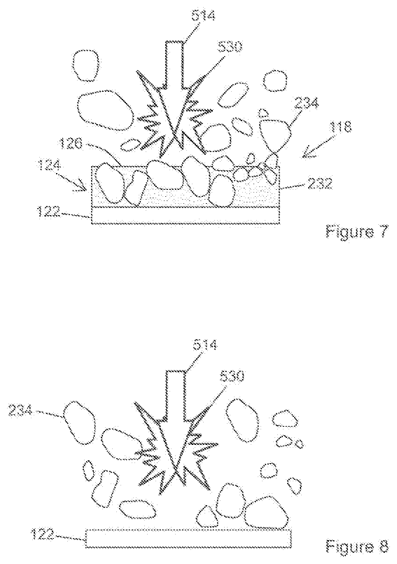

The technique taught herein is further illustrated in FIGS. 7 and 8. FIG. 7 is a cross-sectional elevation view of the coated structure 118 while being subjected to the shock-assisted plasma plume 514 at a given instance of time, and FIG. 8 is a similar view of the coated structure 118 at a later instance of time. The coated structure 118 in this example is the same or similar to that illustrated in FIGS. 2-4. FIG. 8 illustrates the physical disruption of particles 234 as a result of the intense physical impingement of shock waves 530 on the surface 126 of the coating 124. The pressure gradients associated with these shock waves 530 may thus be quite significant. The physical disruption helps to expose new organic layers of the coating 124, which are now free to be subsequently removed by the energetic species of the AP plasma. As shown in FIG. 8, eventually all of the binder 232 (FIG. 7) is ablated and successive shock waves 530 release all inorganic particles 234 down the surface of the substrate 122.

The substrate 122 underlying the material 124 to be removed may have any composition, e.g., metallic, polymeric, ceramic, composite, etc. Moreover, generally no limitation is placed on the type or composition of the material 124 to be removed. As noted above, the material 124 will generally be one in which at least some of the components are responsive to active species of the AP plasma while other components may not be responsive and thus are removed primarily or exclusively by the pressure waves 530 generated in the AP plasma as taught herein. Such materials 124 include, for example, various types of polymeric coatings and paints. Generally, no limitation is placed on the thickness of either the substrate 122 or the material 124 to be removed from the substrate 122. Moreover, the substrate 122 and associated material 124 to be removed are not required to have a simple planar or curvilinear geometry. Instead, the AP plasma source 504 is effective for treating three-dimensional topographies, irregular profiles, and complex geometries. The AP plasma source 504 may be utilized to apply the plasma plume 514 around structural features such as, for example, rivets, or inside narrow channels, or in corners or cracks, etc.

It will also be understood that a “material,” “coating,” “layer,” “film” or the like as used herein encompasses multi-layered, single-layer, or composite materials. For instance, a given polymeric material may include a protective overcoat, an adhesion-promoting layer, or the like. A paint may include a primer layer, a topcoat, etc. The AP plasma source 504 is effective for all such layers or strata of a multi-layered material down to the underlying substrate. The AP plasma source 504 may also be utilized to precisely remove one or more selected layers of a multi-layered material, leaving underling layers intact on the substrate.

FIG. 9 is a lengthwise cross-sectional view of an example of an AP plasma source 904 that may be configured for producing shock waves in the plasma plume. The AP plasma source 904 includes an axially elongated plasma-generating chamber 942 or other structure that serves as a ground electrode for generating plasma and as a conduit for flowing gases and plasma. The plasma-generating chamber 942 may be enclosed in an electrically- and thermally-insulating housing (not shown). A “hot” or powered electrode 946 is located in the plasma-generating chamber 942. Electrical connections to the hot electrode 946 may be made through a dielectric structure 950 located at the proximal end of or in the plasma-generating chamber 942. One or more gas inlets 958 may be formed through the dielectric structure 950 in fluid communication with the plasma-generating chamber 942. The gas inlets 958 may be placed in fluid communication with the gas supply source 508 (FIG. 5). Accordingly, the gas inlets 958 provide a flow path for plasma-generating gas fed to a region 962 within the plasma-generating chamber 942 proximate to the hot electrode 946. In operation, the plasma is generated in this region 962 and subsequently flows with the gas flow toward a nozzle 910 positioned at a distal end of the plasma-generating chamber 942.

In one embodiment of the invention, the AP plasma source 904 includes a particle supply, a gas source providing gas for transport of the particles from the gas source, and a particle inlet/delivery tube 944 feeding the particles into the plasma flowing through nozzle 910 positioned at the distal end of the plasma-generating chamber 942. U.S. Pat. Appl. Publ. No. 2006/0090593 (the entire contents of which are incorporated herein by reference) describes spray process to provide a method of coating fine metal particles, including aluminum and copper, onto a work piece. While the present invention is not so limited, the techniques described therein for entraining particles in a gas stream can be used here such as adding particles to one or more feed hoppers. A compressed gas from the gas source would enter the hopper of the particle supply and carry the particles to the plasma chamber 962 which would constitute a mixing chamber. Here, in the present invention, the particles would mix with the plasms gas to provide a particle-gas stream. The particle-gas stream including the particles and the plasma would be accelerated into nozzle 910 forming a supersonic jet. Typically, in the cold spray guns, the gas flow is already close or at supersonic speed at the point where the particles are injected into a fast, hot, gas stream. The room temperature particles with almost zero velocity are then heated by the hot, fast moving gas stream, introduced into a converging/diverging nozzle, and accelerated within the nozzle to speeds that are near supersonic or supersonic.

In one embodiment, the plasma gas comprises pure helium. In another embodiment, a mixture of helium with a minor component (less than 20%, preferably less than 10%, and more preferably less than 5% of an oxidizing or nitrifying gas such air, oxygen, water vapor, nitrogen, etc.). The lower dilutions mean that the thermal and transport properties are not significantly deviated from that of pure helium which has a high thermal conductivity and a higher speed of sound than air. Other plasma gasses can be used, and the present invention is not limited to the helium based gas mixtures noted above.

According to another implementation, a piezoelectric material such as a suitable ceramic or polymer is positioned in the AP plasma source so as to enable an electrical output from the power supply to induce the piezoelectric effect. For example, the structure 950 shown in FIG. 9 may serve as the piezoelectric element. In this case, the electrical field impressed between the hot electrode 946 and the plasma-generating chamber 942 drives the structure to vibrate. The vibrations are transferred to the plasma and yield pressure waves in the plasma plume, which are utilized to impact a coated structure as described above. The piezoelectric material may be selected so as to match up with the drive frequency as closely as possible for optimizing the piezoelectric effect. Ideally, the drive frequency utilized creates a resonance condition (or other condition that promotes the piezoelectric effect) in the structure 950, although it will be appreciated that various off-resonant frequencies may be sufficient for producing pressure waves effective for the coating removal applications contemplated herein.

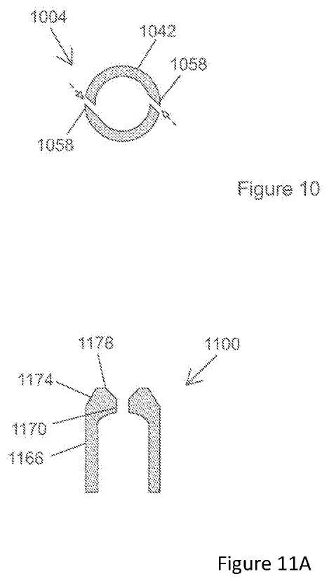

FIG. 10 is a cross-sectional view of another example of an AP plasma source 1004, in a transverse plane perpendicular to the flow of gases through an axially elongated plasma-generating chamber 1042. In this example, gas inlets 1058 are oriented at an acute angle (e.g., 45 degrees) relative to the central, longitudinal axis of the plasma-generating chamber 1042. By this configuration, gas is introduced into the AP plasma source 1004 with a significant tangential vector and consequently flows in the axial direction in a vortex flow pattern or path. The tangential gas inlets 1058 may be utilized in any of the implementations disclosed herein.

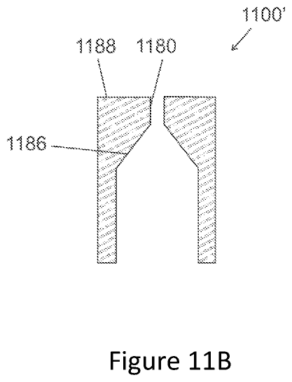

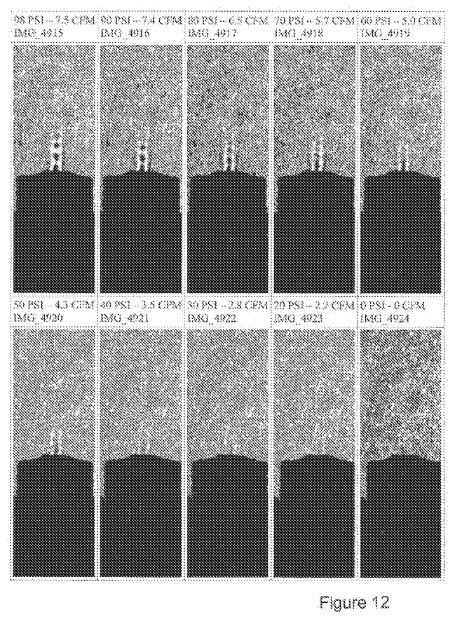

FIG. 11A is a cross-sectional view of an example of a nozzle 1110 that may be utilized in any of the implementations disclosed herein. In this example, the nozzle 1110 has a converging-diverging design. Specifically, the nozzle 1110 includes a first, converging section 1166 having an inside diameter that tapers down to a second, reduced-diameter section or throat 1170. The throat 1170 transitions to a third, diverging section 1174 having an inside diameter that increases to a larger-diameter nozzle exit 1178. The nozzle 1110 may be dimensioned appropriately as a means for producing pressure waves or shock waves as described above. Alternatively, the nozzle 1110 has only a converging design, i.e., lacks the diverging section 1174. Converging nozzles as well as converging-diverging nozzles have been found by the inventors to be effective for producing pressure waves under appropriate operating conditions.

FIG. 11B is a cross-sectional view of another example of a nozzle 1110′ that may be utilized in any of the implementations disclosed herein. In the nozzle 1110′, there is straight taper converging section 1186 having an inside or first diameter that tapers down to a second, reduced-diameter section or throat 1180. The convergence angle of the first converging section may range from approximately 5 degrees to 175 degrees and more preferably around 120 degrees. Converging section 1186 may be considered to be that of the inside of cone open at the most tapered part at throat 1180. The throat 1180 transitions to nozzle exit 1188. The nozzle 1110′ may be dimensioned appropriately as a means for producing pressure waves or shock waves as described above. Commonly used dimensional rangers for one implementation of the design range from for the first cylindrical diameter is between 15 mm and 5 mm in diameter with a more preferred diameter of 7.5 mm. The second diameter in this implementation can range from 4 mm to 1 mm in diameter with a preferred size of 2.5 mm in diameter. These size ranges are only valid at specific operational flow rates and pressures. For this general implementation the flow rates are between 1 SCFM to 7.5 SCFM and pressures ranging from 30 psi to 150 psi.

In another implementation, an AP plasma source having a configuration similar to that shown in FIGS. 5 and 9, with a converging nozzle (i.e., a straight conical cross-sectional flow area without being followed by a diverging section), has been fabricated and evaluated. The AP plasma source repeatably and reliably produces a plasma plume characterized by shock waves, as evidenced by a clearly visible pattern of shock diamonds in the plasma plume, and achieved superior etch rates on coated samples as compared to conventional AP plasma sources unassisted by shock waves. The AP plasma source generated an air plasma using air at about room temperature as the feed gas. The air may be fed to an AP plasma source of this type at a pressure ranging from 30-150 psi and at a flow rate ranging from 1-7.5 CFM. In another example, the pressure range is 65-95 psi. In another example, the flow rate range is 1-4 CFM. Pressures higher than 150 psi may also be implemented to produce shock waves. In a more general example, the pressure may be 30 psi or greater and the flow rate may be 1 CFM or greater.

In a particular example useful for the cleaning of metal surfaces such as titanium, mild steels (DH 36, A 36), high strength steels HSLA 65, HSLA 100, HY 80, HY 100, HY 120, and HY 140), the following atmospheric plasma conditions using air as the plasma gas is provided:

Air Flow: 20-200 SLM, preferred 100 SLM

Plasma Power: 0.3 kW to 5 kW, preferred 2.0 kW

Electrode Voltage: 500 V to 4000 V, preferred 1200 V

Frequency: DC to 3000 MHz, preferred 70-250 kHz

Substrate Temp: −50° C. to +600° C., preferred +20° C. (or just below the annealing point of the substrate)

Substrate condition: descaled metal with smooth surface roughness less than 0.01 mil to 5 mil.

In a first test, paint was applied to an aluminum panel which had been cleaned within the AP plasma cleaning conditions noted above, and the paint was air dried and cured 7 days. The aluminum panels were bent over cylindrical mandrels of various diameters. The film is rated visually or microscopically for cracking as “Pass” or “Fail.” The paint on the cleaned aluminum surface passed this first test. Paint coatings applied to the AP plasma cleaned surface have also been tested according to ASTM D4541, which is a standard historically used to evaluate the adhesion of epoxies to steel surface. These paint coatings passed the ASTM D4541 standard tests.

Accordingly, in one embodiment of the present invention, there is provided an atmospheric plasma cleaned surface capable of adhering cold spray coatings (and other coatings) thereto. The atmospheric plasma cleaned surface is typically free or substantially free of undesirable organic and inorganic residue. By substantially free, the atmospheric plasma cleaned surface contains less than 2% of any of the undesirable residue thereon as compared to the native materials of the surface being cleaned constituting 100% for a perfectly clean surface, or more preferably less than 1%, or still more preferably less than 0.5%. These cleaned surfaces in one embodiment can contain other elements which promote adhesion of the coating to the material of the substrate.

In a second test following testing methods of ASTM D4541, which as noted above has been used to evaluate the adhesion of epoxies to steel surface, the adherence of cold spray coatings to the atmospheric plasma cleaned surfaces was evaluated. In this second test, the cold spray coatings were applied to a steel surface (such as for example one of the high-strength steels described above) after the above-described atmospheric plasma cleaning had been performed. The steel substrate with the cold spray coating was then adhered to a test-loading fixture with a standard-mandated adhesive. After curing, tension is applied to pull the test-loading fixture and thus pull the cold spray coating away from the steel substrate. The force applied to the test-loading fixture is monitored until ether a plug of material of the coating is detached or a specified value of force is reached. The cold spray coatings applied to the atmospheric plasma cleaned steel surfaces passed this second test with no delamination to the rated loading.

FIG. 12 is a set of shadowgrams (Schlieren images) of output flows from an AP plasma source at various air pressures and flow rates. In order, starting from the upper left image and ending with the lower right image, the conditions were: 98 psi and 7.5 CFM; 90 psi and 7.4 CFM; 80 psi and 6.5 CFM; 70 psi and 5.7 CFM; 60 psi and 5.0 CFM; 50 psi and 4.3 CFM; 40 psi and 3.5 CFM; 30 psi and 2.8 CFM; 20 psi and 2.2 CFM; and 0 psi and 0 CFM. In these examples, it can be seen that the shock waves are more visible or pronounced at the higher pressures and flow rates as compared to the lower pressures and flow rates.

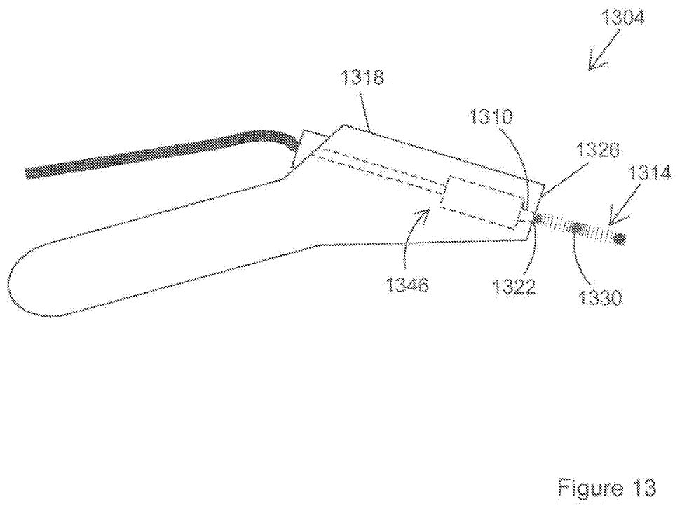

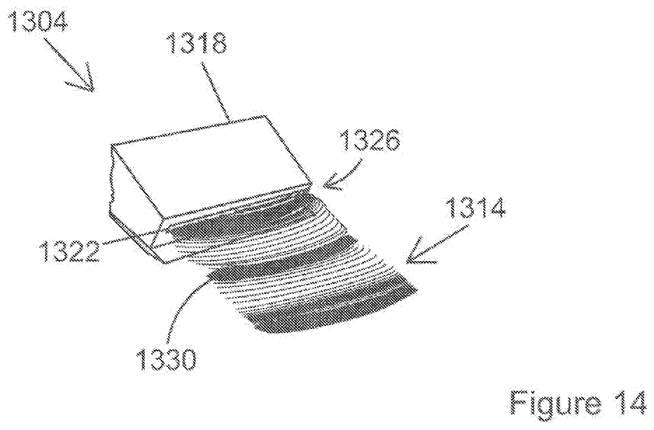

FIG. 13 is a side elevation view of another example of an AP plasma source 1304 according to another implementation, referred to herein as a “plasma pen.” The plasma pen device is typically a device which provides a laterally-extending plume of the plasma gas into the ambient environment, as shown in FIG. 14. The intense plume of the plasma pen device provides for fast removal of any undesirable residue on the surface of the substrate to be cleaned and provides a broad swath for the treatment.

In one embodiment, the plasma sources described above can be operated with enriched gas mixtures which can increase the flux of oxygen or other desired chemical terminations groups onto the substrate. Different chemical groups may be chosen to enhance the adhesion for the specific chemistry of the substrate and the cold sprayed deposited material. For example, the plasma sources can be operated with nitrogen to produce atomic nitrogen species which can be used to nitride surfaces which may be beneficial to bonding metals or metal cermets that have a high affinity for nitrogen. In one embodiment, alternative gases or materials may be used to enhance the chemical and electrical properties by diffusion into the substrate's lattice. As noted above, in one embodiment, this can be accomplished by adding to the plasma gas cleaning the surface, preferably after the surface has been cleaned, compounds containing but not limited to B, C, N, O, F, Cl, S, P, Si, Br, I, Se, Te. Depending on the type of cold spray composition it may be preferred to use a plasma chemical species other than oxygen to activate the metallic surface. One example would be using a nitride to bond with nitride forming alloy systems.

FIG. 14 is a front perspective view of a front portion of the AP plasma source 1304 providing an elongated plasma plume. The AP plasma source 1304 includes one or more plasma-generating units 1346 in a main body 1318 communicating with one or more nozzles (or a manifold) 1310. The nozzle(s) or manifold 1310 are set back in the main body 1318 and communicate with a slot-shaped plasma outlet 1322 that opens at a distal end 1326 of the main body 1318. By this configuration, the AP plasma source 1304 produces a wide, predominantly linear or horizontally-oriented plasma plume or “plasma line” 1314 with wide, predominantly linear or horizontally-oriented shock waves or pressure waves 1330.

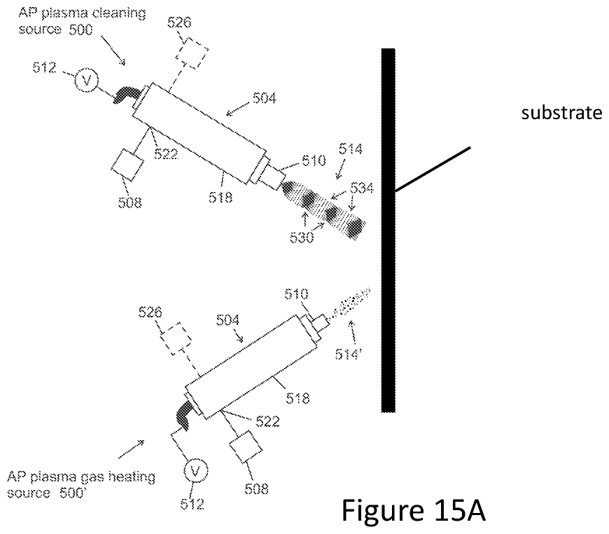

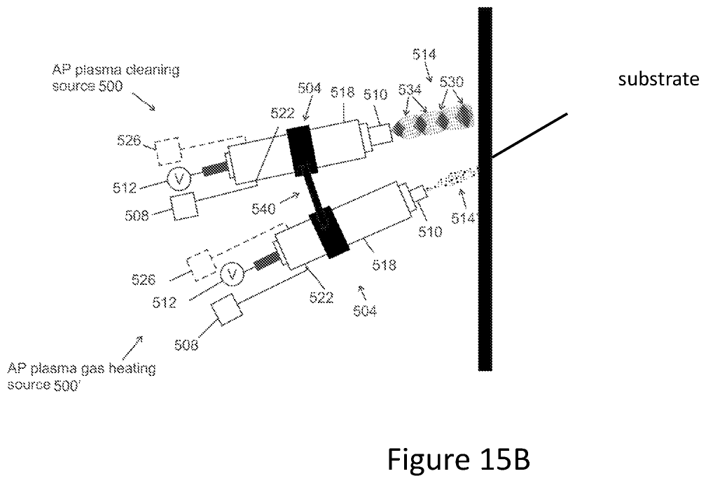

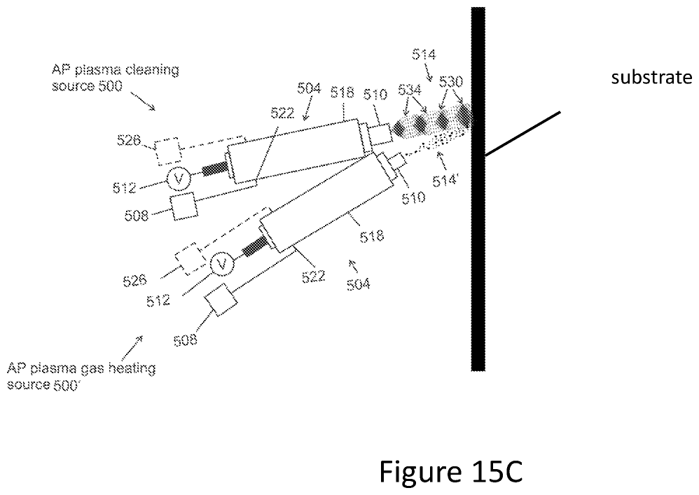

FIG. 15A is a diagram of one embodiment of an AP plasma application system according to implementations disclosed herein for preheating precursor particles during coextensive plasma cleaning and cold spray coating. An AP plasma cleaning source 500 and an AP plasma gas heating source 500′ shown in FIG. 15A can have the same components as shown in FIG. 5, and are not further described except for the differences. Here, AP plasma cleaning source 500 and AP plasma gas heating source 500′ have respectively a first axis and a second axis that are both directed to a substrate to be treated. Accordingly, the first axis and the second axis can be directed respectively to a first point and a second point on a substrate to be treated. The second point in one embodiment can be within the plasma plume from the plasma-generating chamber 504 contacting the substrate to be treated. The second point may be outside (as shown) the plasma plume from plasma-generating chamber 504 of AP plasma cleaning source 500. When the second point is outside the plasma plume from plasma-generating chamber 504 of AP plasma cleaning source 500, movement of the substrate relative to the AP plasma cleaning source 500 or relative to AP plasma gas heating source 500′ can scan the first point and second point on the substrate such that the cold spray coating is applied to a region of the substrate where the plasma plume has been momentarily been moved from.

FIG. 15B is a diagram of another embodiment of an AP plasma application system according to implementations disclosed herein for preheating precursor particles during coextensive plasma cleaning and cold spray coating. Here, the components are the same as above in FIG. 15A, but AP plasma cleaning source 500 and AP plasma gas heating source 500′ are arranged such that these chambers both are oriented in the same general direction and have respectively a first axis and a second axis that are directed to a substrate to be treated. As above, the first axis and the second axis can be directed respectively to a first point and a second point on a substrate to be treated. The second point can be within or outside the plasma plume from plasma-generating chamber 504 of AP plasma cleaning source 500 contacting the substrate. When the second point (as shown) is outside the plasma plume from plasma-generating chamber 504 of AP plasma cleaning source 500, movement of the substrate relative to the AP plasma cleaning source 500 or relative to AP plasma gas heating source 500′ can scan the first point and second point on the substrate such that the cold spray coating is applied to a region of the substrate where the plasma plume has been momentarily been moved from. As shown in FIG. 15B, a linkage 540 connects the sources 500 and 500′ together.

FIG. 15C is a diagram of another embodiment of an AP plasma application system according to implementations disclosed herein for preheating precursor particles during coextensive plasma cleaning and cold spray coating. Here, the components are the same as above in FIG. 15A, but AP plasma cleaning source 500 and AP plasma gas heating source 500′ are arranged such that these chambers both are oriented in the same general direction and have respectively a first axis and a second axis that are directed to a common point on a substrate to be treated. In this case, the cold spray coating is applied to a region of the substrate where the plasma plume is simultaneously cleaning.

In one embodiment, the AP plasma gas heating source 500′ could be replaced with a non-plasma cold spray apparatus such as that described above in U.S. Pat. Appl. Publ. No. 2006/0090593.

As noted above, in one embodiment, a coating to be applied to substrate 122 (once the substrate surface has been cleaned and/or otherwise treated with the plasma treatment of the present invention) can be a cold spray coating of a particulate material (e.g., pure metal, a pure metal alloy, a cermet, a mixture of metal and inorganic particulates, or polymers, composite particles with fibers and matrix material or incorporation of nanoparticles, nanowires, nanotubes or other nano sized particles of varied morphologies) depositing by entraining those particles or mixtures of those components in a supersonic velocity stream. U.S. Pat. No. 8,591,986, the entire contents of which are incorporated herein by reference, describes that one method used for producing bonded metallic coatings on substrates is cold spray technology. When using a cold spray technology (also referred to herein as simply “cold spray”), particles are mixed with a gas and the gas and particles are subsequently accelerated in a supersonic jet, and the gas and particles are maintained at a sufficiently low temperature to prevent melting of the particles. Aluminum coatings and higher temperature materials, such as copper, stainless steel, nickel, nickel-base superalloys, and titanium-base alloys can be spray coated using the AP plasma assisted cold spray process of the present invention. Other metals, polymers, composites (such as ceramic and carbon reinforced metals), and carbides (or other hard ceramic phase materials) can be spray coated using the AP plasma assisted cold spray process of the present invention, including also for example the above-noted composite particles with fibers and matrix material or incorporation of nanoparticles, nanowires, nanotubes or other nano sized particles of varied morphologies. In this case, these composites may be included in another phase.

Indeed, the inventors of this invention have realized that the atmospheric pressure plasma system has the capability to heat the supersonic gas prior to introduction of the cold spray particles for deposition. The inventors of this invention have further realized that the atmospheric pressure plasma system has the capability to not only prepare the surface for cold spray coating, and heat the supersonic gas prior to introduction of the cold spray particles, but also can treat the cold spray particles in transit and as these particles form the coating to remove undesirable residue from their surfaces which would inhibit fusion of the particles together as they impact the substrate surface and coalesce into a dense adherent cold spray coating. Due to the heating of the particles inside the AP plasma source and the in-situ cleaning of the particles, it is possible according to one embodiment of the invention to use gasses other than pure helium for a AP plasma assisted cold spray process as the coating process need not rely on particles traveling at the speed of sound in helium in order to adhere to a substrate and form a consolidated coating. Indeed, for films where porosity is a desirable property, the gasses other than pure helium are especially useful, and the use of other gases such as nitrogen and argon represent a way to control/vary the porosity of the resultant films.

Accordingly, the plasma generated by the AP plasma source may (in a first mode) function as a cold, or non-thermal, plasma containing one or more reactive species suitable for chemically interacting with a surface to be coated in a manner sufficient for causing any undesirable residue to be removed from its surface. Generally, the reactive species may include photons, metastable species, atomic species, free radicals, molecular fragments, monomers, electrons, and ions. The reactive species desired to be produced will generally depend on the type of coating or undesirable residue to be removed. In the case of various polymeric coatings and paints, a highly oxidizing plasma is effective, in which case the predominant reactive species may include O, O₂* (the asterisk designating the metastable form of diatomic oxygen), and/or O₃. The high plasma density air plasma of the present invention can produce a high fluence of atomic oxygen compared to air in a gas state. The increased diffusivity of atomic oxygen coupled with its extremely reactive chemical affinity allows the atomic oxygen to rapidly and completely clean the surface of organic contaminants. Atomic oxygen has a much greater chemically reactivity than 02 and greater than even ozone. In various implementations, air supplied by the plasma-generating gas supply source 508 may be sufficient for generating an effective amount of oxygen-based energetic species for removing various types of polymeric coatings or paints. Additional non-limiting examples of active species that may be formed in the plasma and utilized for material removal include fluorine, chlorine, bromine, iodine, nitrogen, or sulphur.

One or more of these species may be utilized, for example, to selectively etch (or enhance the etching selectivity of) a primer layer or adhesion layer if a specialized chemistry or primer formulation has been employed in the coated structure. For example, in the case of a topcoat that exhibits preferential etching by oxygen, oxygen species could be used so that the topcoat layer is preferentially etched relative to an underlying primer layer. Furthermore, the plasma treatment can be performed manually or robotically with overlapping surface coverage to ensure complete treatment area coverage. An oxidizer may also be mixed with an inert gas or relatively inert gas such as nitrogen or natural air mixtures. Certain gas mixtures may be used to create enhanced ionization of an oxidizing or reducing component by means of a Penning ionization reaction or other similar ionization mixtures that promote enhanced ionization through appropriate ion energy exchanges in the plasma. It is also possible to use reducing plasma species such as hydrogen or ammonia. It is also possible to use neutral or inert gases to energetically bombard the interface layer and promote decohesion at the bond line. The type of oxidizing species in the plasma plume may be adjusted for specific coating chemistries to maximize the etch rate of the coating. For instance, certain coating chemistries may be quite resistant to an oxygen-containing oxidizer but could be quite easily etched by a fluorinated oxidizer.

In one embodiment, the plasma treatment of the present invention etches organic residues on the surface to be coated and leaving the surface nearly atomically clean of foreign organic and inorganic substances. Since an air plasma is typically the source of the energetic species (as noted above), the surfaces to be coated, if metallic, would most likely contain some amount of native oxide. Yet, the native oxides are not necessarily detrimental and may even foster adhesion from the coating layer to the surface of the substrate being coated.

The plasma generated by the AP plasma source may (in a second mode) utilize energetic species from the plasma to increase the surface energy of the metal surface or substrate and thereby reduce the surface tension which may promote wetting of the surface by the high speed metal particles produced by the cold spray coating process. In this mode, the plasma surface treatment can create active chemical sites that can bond chemically with the cold sprayed metal. In one embodiment, this can be accomplished by adding to the plasma gas, preferably after the surface has been cleaned, compounds (like siloxanes, diboranes, silazanes, etc) containing but not limited to B, C, N, O, F, Cl, S, P, Si, Br, I, Se, Te. These compounds in one embodiment can form surface monolayers of these chemical groups promoting adhesion to substrate's base metallic material. In one embodiment, the exposure of such surface monolayers to a coating material may alter or further change these surface chemical groups to promote adhesion.

The inventors of this invention have realized that the atmospheric pressure plasma treatment of the present invention may be used as a bonding adhesion promoter that enhances the adhesion of cold sprayed coating layers, thereby permitting smooth surfaces with little roughness or surface profile to be coated with a cold spray coating with improved adhesion. One important factor that the inventors of this invention have realized is the plasma activated surface (having thereon reactive species such as OH species, nitrogen species, hydrogen species, and reactive metal species) has a limited effective lifetime with a degradation half-life or a “shelf life” which becomes less effect as time proceeds after the initial plasma activation when the surface is exposed to ambient conditions.

Accordingly, in one embodiment of the invention, the coating is applied within 30 minutes of the surface being cleaned/activated so that the energetic species are still active on the surface at the time of material deposit. In one embodiment of the invention, the coating is applied within 10 minutes of the surface being cleaned/activated so that the energetic species are still active on the surface at the time of material deposit. In one embodiment of the invention, the coating is applied within 1 minute of the surface being cleaned/activated so that the energetic species are still active on the surface at the time of material deposit. The timeframes noted above are exemplary and depend on factors such as substrate type and ambient conditions.

In one embodiment of the invention, the coating and the plasma cleaning are applied simultaneously to the surface being cleaned so that the energetic species are active on the surface as the coating material deposits. In one embodiment of the invention, the coating is applied in a region where the plasma plume is contacting the surface so that the energetic species are active on the surface as the coating material deposits. In one embodiment of the invention, the coating is applied in a region where the plasma plume has been momentarily been moved from so that the energetic species are active on the surface as the coating material deposits.

Alternatively, a dielectric barrier device (DBD) could be used to generate a plasma for activating the surface. These DBD systems would operate at lower plasma densities and result in likely slower but nonetheless effective treatments.

In general, any atmospheric plasma device that produces a sufficient flux of energetic plasma species could be used to treat (clean and activate) the surface in the manner described above. However, many atmospheric plasma sources would not produce a significant flux of energetic species to permit an industrially feasible process to be created.

The plasma generated by an AP plasma source may (in a third mode) function as a plasma heater to heat up a gas flowing (such as He or Nitrogen or other gasses) at supersonic speed out of the plasma nozzle. As noted above, particles for cold spraying are injected into in a flow of carrier gas such as a heated helium or nitrogen or other pure or gas mixtures which heats the particles to temperatures suitable for the composition of particles being deposited but not to exceed the melting point temperatures of the particles. The heated particles in the supersonic flow travel at high velocity before the particles impact the solid substrate. The particles having a high kinetic energy and upon impacting the solid surface deform and coalesce to create a highly dense layer with minimal porosity.

When cold spray particles (especially metal particles) impact the plasma treated surface of the present invention, the enhanced chemical reactivity imparted by the air plasma treatment discussed above enhances the bonding creating a chemical as well as a mechanical bond. Because the bonding is now chemical and not merely mechanical, an enhanced adhesion can occur on relatively smooth surfaces which may reduce the need for or possibly eliminate entirely the need for grit blasting or profiling the surface in another step prior to plasma treating the substrate to be coated. While discussed above, often in the context of the cold spraying of metal particles, the particle source for the cold spray can include a pure metal, a pure metal alloy, a cermet, a mixture of metal and inorganic particulates, or polymers.

In one embodiment of the invention, the cold spray process is modified so that the cold spray particles are plasma treated in the process of being ejected from the cold spray nozzle The AP plasma source of the present invention can plasma treat the cold spray particles as they exit the cold spray nozzle and prior to impact on the substrate.

In a conventional cold spray process, the particles and the carrier gas stream are typically heated to 100° C.-600° C. as part of the process before the particles are ejected through an appropriately shaped nozzle. This heating of the gas stream has conventionally used resistive metal heating elements that the carrier gas must flow across. This part of the conventional process is inefficient and requires a substantial volume of space to house the heater and associated power supplies. In one embodiment of the invention, the AP plasma source is operated at higher power densities such that the plasma serves as a heater providing the required temperature to the particles (e.g., the 100° C.-600° C.) while in a simultaneous process the cold spray particles are plasma treated as they transit to the substrate. For example, the plasma heater can be inserted inline with the flow of carrier gas and metal particles which would take up significantly less volume and would increase electric efficiency when compared with conventional resistive element gas heaters.

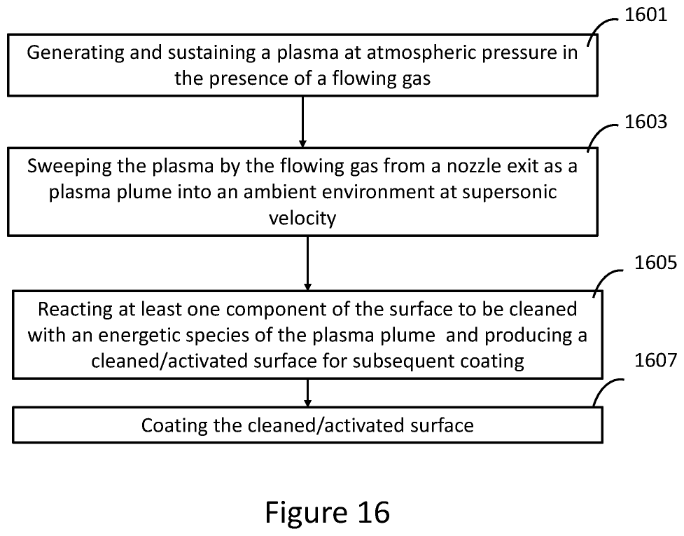

In operation of the AP plasma source, the control and power source 512 may be programmed/controlled to operate the AP plasma source in a manner in which a method for cleaning a surface of a substrate with atmospheric pressure plasma pressure waves prior to application of a coating onto the cleaned surface of the substrate is accomplished as illustrated by the flow chart in FIG. 16.

In FIG. 16, at 1601, a plasma is generated (and sustained) at atmospheric pressure in the presence of flowing gas. The plasma includes an energetic species reactive with one or more components on the surface of the substrate. At 1603, the plasma is swept by the flowing gas from a nozzle exit, or from a slot-shaped plasma outlet, as a plasma plume (that optionally can include periodic regions of high plasma density and low plasma density) exiting into an ambient environment at supersonic velocity. At 1605, a least one component of the surface of the substrate reacts with the energetic species. Furthermore, at 1605, at least one other component of the surface of the substrate is physically impacted and moved by the gas flowing at supersonic velocity to produce a cleaned and/or activated surface. At 1607, a coating such as a cold spray coating can be applied to the cleaned surface because the cleaned and/or activated surface having foreign substances removed and having been activated by the energetic species is in a state to have a coating applied thereto.

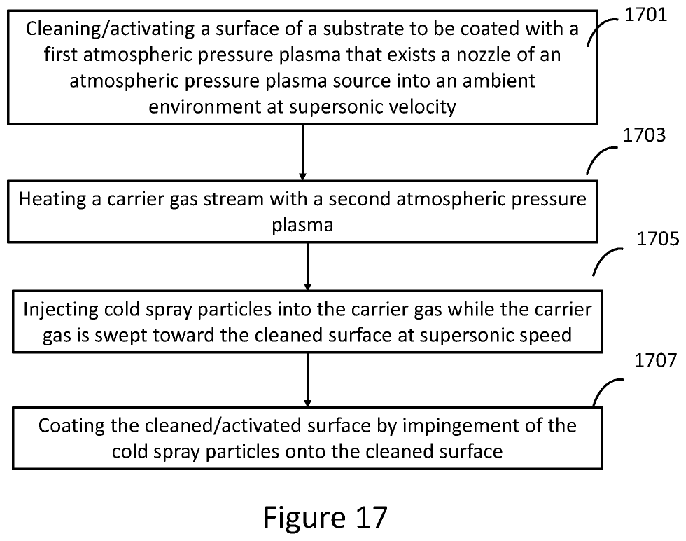

In operation of the AP plasma source, the control and power source 512 may be programmed/controlled to operate the AP plasma source in a manner in which a method for coating a surface of a substrate with a cold spray coating is accomplished as illustrated by the flow chart in FIG. 17.

In FIG. 17, at 1701, a surface of a substrate to be coated is cleaned and/or activated with a first atmospheric pressure plasma that exits a nozzle of an atmospheric pressure plasma source into an ambient environment at supersonic velocity. At 1703, heating a carrier gas stream with the first atmospheric pressure plasma or a second atmospheric pressure plasma. At 1705, injecting cold spray particles into the carrier gas while the carrier gas is swept toward the cleaned and/or activated surface at supersonic speed. At 1707, coating the cleaned and/or activated surface by impingement of the cold spray particles onto the cleaned surface.

At 1703, any of the operating conditions below may be used to heat the AP plasma to a state where the particles introduced into the plasma reach a preferred elevated temperature, but not to exceed the particle's melting temperature.

### Example 1

He Flow for AP plasma: 150-8500 SLM, preferred 2800 SLM

Pressure: 1 MPa-7 MPa, preferred 3 MPa

Plasma Power: 0.3 kW to 100 kW, preferred 35 kW

Electrode Voltage: 500 V to 8000 V, preferred 3000 V

Frequency: DC to 3000 MHz, preferred 70-250 kHz

Particle carrier flow: He: 10-200 SLM, preferred 50 SLM

### Example 2

He Flow for AP plasma with <10% O₂, N₂, NH₃, or Air: 150-8500 SLM, preferred 2800 SLM

Pressure: 1 MPa-7 MPa, preferred 3 MPa

Plasma Power: 0.3 kW to 100 kW, preferred 30 kW

Electrode Voltage: 500 V to 8000 V, preferred 5000 V

Frequency: DC to 3000 MHz, preferred 70-250 kHz

Particle carrier flow: He: 10-200 SLM, preferred 50 SLM

### Example 3

He Flow for AP plasma with less than 4% H₂ (below explosive limit), 150-8500 SLM, preferred 2800 SLM

Pressure: 1 MPa-7 MPa, preferred 3 MPa

Plasma Power: 0.3 kW to 100 kW, preferred 35 kW

Electrode Voltage: 500 V to 8000V, preferred 5000V

Frequency: DC to 3000 MHz, preferred 70-250 kHz

Particle carrier flow: He: 10-200 SLM, preferred 50 SLM

At 1705, the particles are entrained in a gas stream inside of the AP plasma source being used for cleaning and/or activating the substrate or entrained in a separate AP plasma source being used exclusively for superheating the particles.

By this operation combining AP plasma cleaning of the surfaces to be coated and the particles used in the cold spray coating process along with the kinetic energy of the cold spray process, unique coating structures can be fabricated. For example, aluminum adherence to stainless steel has conventionally been made by an explosion bonding process. In the present invention, a stainless steel article could be cleaned and then cold-sprayed with aluminum or aluminum alloy particles to form an aluminum coated stainless steel article. Similarly, copper oxides are generally considered mechanically weak. By cleaning a copper surface by the AP plasma cleaning process and then a subsequent coating of the copper by a metal that alloys with copper (such as tin, zinc, nickel, silicon, silver) or a subsequent coating of the copper by a polymer, and then with or without subsequent metallization(s) or polymeric coating, a unique copper panel resistant to copper oxidation (weathering) can be produced which provides a panel thus resistant to “greening.” Additionally, materials considered not to readily alloy with copper such as tungsten could be used in the AP plasma spray process. In other examples, composites of polymers, metals, and/or ceramics can be formed as a substrate-coating combination or as a composite coating on various substrates. Other examples of materials that can be produced as composites using the inventive AP plasma heating/cold spray/cleaning process include but are not limited to Cobalt+Tungsten Carbide, Nickel+Chrome Carbide, Inconel+Chrome Carbide as well as other metal+ceramic, metal+semiconductor, metal+polymer combinations, also including polymer alloys and including a polymer matrix having therein metals and/or semiconductors.

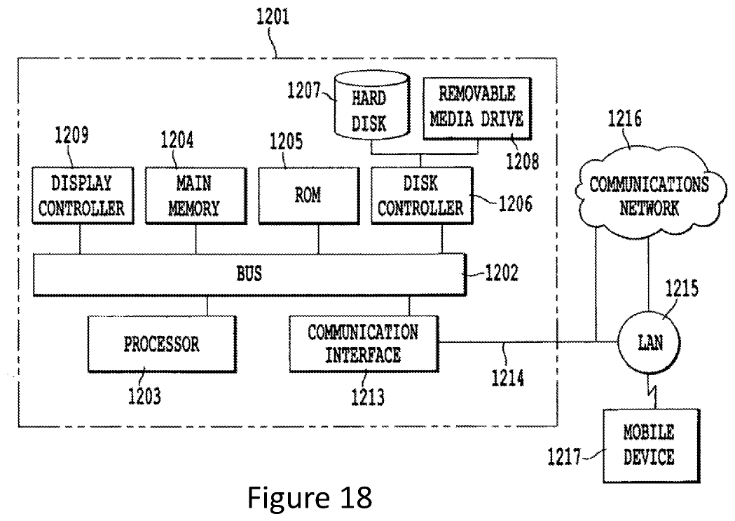

In operation of the AP plasma source, the control and power source 512 may include a computer system 1201 (as illustrated in FIG. 18) for implementing various embodiments of the invention. The computer system 1201 may be used as the control and power source 512 to perform any or all of the functions described above (for example to perform some or all of the steps depicted in FIGS. 16 and 17). The computer system 1201 includes a bus 1202 or other communication mechanism for communicating information, and a processor 1203 coupled with the bus 1202 for processing the information. The computer system 1201 also includes a main memory 1204, such as a random access memory (RAM) or other dynamic storage device (e.g., dynamic RAM (DRAM), static RAM (SRAM), and synchronous DRAM (SDRAM)), coupled to the bus 1202 for storing information and instructions to be executed by processor 1203. In addition, the main memory 1204 may be used for storing temporary variables or other intermediate information during the execution of instructions by the processor 1203. The computer system 1201 further includes a read only memory (ROM) 1205 or other static storage device (e.g., programmable read only memory (PROM), erasable PROM (EPROM), and electrically erasable PROM (EEPROM)) coupled to the bus 1202 for storing static information and instructions for the processor 1203.

The computer system 1201 also includes a disk controller 1206 coupled to the bus 1202 to control one or more storage devices for storing information and instructions, such as a magnetic hard disk 1207, and a removable media drive 1208 (e.g., floppy disk drive, read-only compact disc drive, read/write compact disc drive, compact disc jukebox, tape drive, and removable magneto-optical drive). The storage devices may be added to the computer system 1201 using an appropriate device interface (e.g., small computer system interface (SCSI), integrated device electronics (IDE), enhanced-IDE (E-IDE), direct memory access (DMA), or ultra-DMA).

The computer system 1201 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)).

The computer system 1201 may also include a display controller 1209 coupled to the bus 1202 to control a display for displaying information to a computer user. The computer system includes input devices, such as a keyboard and a pointing device, for interacting with a computer user and providing information to the processor 1203. The pointing device, for example, may be a mouse, a trackball, or a pointing stick for communicating direction information and command selections to the processor 1203 and for controlling cursor movement on the display. In addition, a printer may provide printed listings of data stored and/or generated by the computer system 1201.

The computer system 1201 performs a portion or all of the processing steps of the invention (such as for example those described in relation to FIGS. 16 and 17) in response to the processor 1203 executing one or more sequences of one or more instructions contained in a memory, such as the main memory 1204. Such instructions may be read into the main memory 1204 from another computer readable medium, such as a hard disk 1207 or a removable media drive 1208. One or more processors in a multi-processing arrangement may also be employed to execute the sequences of instructions contained in main memory 1204. In alternative embodiments, hard-wired circuitry may be used in place of or in combination with software instructions. Thus, embodiments are not limited to any specific combination of hardware circuitry and software.

As stated above, the computer system 1201 includes at least one computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the invention includes software for controlling the computer system 1201, for driving a device or devices for implementing the invention, and for enabling the computer system 1201 to interact with a human user. Such software may include, but is not limited to, device drivers, operating systems, development tools, and applications software. Such computer readable media further includes the computer program product of the invention for performing all or a portion (if processing is distributed) of the processing performed in implementing the invention.

The computer code devices of the invention may be any interpretable or executable code mechanism, including but not limited to scripts, interpretable programs, dynamic link libraries (DLLs), Java classes, and complete executable programs. Moreover, parts of the processing of the invention may be distributed for better performance, reliability, and/or cost.

The term “computer readable medium” as used herein refers to any medium that participates in providing instructions to the processor 1203 for execution. A computer readable medium may take many forms, including but not limited to, non-volatile media, volatile media, and transmission media. Non-volatile media includes, for example, optical, magnetic disks, and magneto-optical disks, such as the hard disk 1207 or the removable media drive 1208. Volatile media includes dynamic memory, such as the main memory 1204. Transmission media includes coaxial cables, copper wire and fiber optics, including the wires that make up the bus 1202. Transmission media also may also take the form of acoustic or light waves, such as those generated during radio wave and infrared data communications.

Various forms of computer readable media may be involved in carrying out one or more sequences of one or more instructions to processor 1203 for execution. For example, the instructions may initially be carried on a magnetic disk of a remote computer. The remote computer can load the instructions for implementing all or a portion of the invention remotely into a dynamic memory and send the instructions. The bus 1202 carries the data to the main memory 1204, from which the processor 1203 retrieves and executes the instructions. The instructions received by the main memory 1204 may optionally be stored on storage device 1207 or 1208 either before or after execution by processor 1203.

The computer system 1201 also includes a communication interface 1213 coupled to the bus 1202. The communication interface 1213 provides a two-way data communication coupling to a network link 1214 that is connected to, for example, a local area network (LAN) 1215, or to another communications network 1216 such as the Internet. For example, the communication interface 1213 may be a network interface card to attach to any packet switched LAN. As another example, the communication interface 1213 may be an asymmetrical digital subscriber line (ADSL) card, an integrated services digital network (ISDN) card or a modem to provide a data communication connection to a corresponding type of communications line. Wireless links may also be implemented. In any such implementation, the communication interface 1213 sends and receives electrical, electromagnetic or optical signals that carry digital data streams representing various types of information.

The network link 1214 typically provides data communication through one or more networks to other data devices. For example, the network link 1214 may provide a connection to another computer through a local network 1215 (e.g., a LAN) or through equipment operated by a service provider, which provides communication services through a communications network 1216. The local network 1214 and the communications network 1216 use, for example, electrical, electromagnetic, or optical signals that carry digital data streams, and the associated physical layer (e.g., CAT 5 cable, coaxial cable, optical fiber, etc). The signals through the various networks and the signals on the network link 1214 and through the communication interface 1213, which carry the digital data to and from the computer system 1201 may be implemented in baseband signals, or carrier wave based signals.

Generalized Statements of the Invention

The following numbered statements describe various aspects of the invention and are not intended to limit the invention except by whatever subject matter here is included in the appended claims

Statement 1. A method for cleaning a substrate with an atmospheric pressure plasma process (e.g. with atmospheric pressure plasma waves), the method comprising: generating a plasma at atmospheric pressure, the plasma comprising an energetic species reactive with one or more components of an undesirable material on the substrate; flowing the plasma from a nozzle exit as a plasma plume exiting into an ambient environment (e.g. at supersonic or subsonic velocities); and exposing the surface of the substrate to the energetic species in the plasma plume to produce an activated surface capable of adhering on contact with a coating material (e.g., from cold spray of particles) to the activated surface.

Statement 2. The method of statement 1, wherein the exposing removes undesirable organic residue from the surface of the substrate.

Statement 3. The method of statement 1 or statement 2, wherein the exposing removes undesirable inorganic residue from the surface of the substrate.

Statement 4. The method of statement 1 (or any of the statements above), wherein the exposing leaves reactive species on the surface of the substrate.

Statement 5. The method of statement 4, wherein the reactive species comprise at least one of OH species, COOH species, carbonyl groups, ether groups, esters, amines, nitrogen species, hydrogen species, and reactive metal species which are not present in the substrate and which promote adhesion between the substrate and the coating material.

Statement 6. The method of statement 1 (or any of the statements above), further comprising applying the coating to the substrate wherein the coating has an adherence to the substrate which passes a mandrel bend test such that, upon bending the substrate with the coating over a cylindrical mandrel prescribed by ASTM D-522, the coating exhibits no delamination.

Statement 7. The method of statement 1 (or any of the statements above), further comprising applying the coating to the substrate wherein the coating has an adherence to the substrate which passes an adherence pull test such that, upon adhering the coating to a test pull fixture using procedures of ASTM D4541, the coating exhibits no delamination when pulled at a force prescribed by the ASTM D4541.

Statement 8. The method of statement 1 (or any of the statements above), wherein the exposing comprises exposing the surface to the plasma plume such that periodic regions of high plasma density and low plasma density impact the surface of the substrate.

Statement 9. The method of statement 8, wherein at least one component of the undesirable material on the substrate reacts with the energetic species and at least one other component of the undesirable material on the substrate is physically impacted and moved by one or more of the regions of high plasma density.

Statement 10. The method of statement 9, wherein the undesirable material comprises an organic component that reacts with the energetic species and an inorganic component that is impacted and moved by one or more of the regions of high plasma density.

Statement 11. The method of statement 9, wherein the regions of high plasma density include respective pressure waves that impact and move the at least one other component, and the pressure waves comprise shock waves.

Statement 12. The method of statement 1 (or any of the statements above), wherein generating the plasma comprises applying an electrical field to a stream of air, and the energetic species includes an oxidizing-inclusive species, or wherein generating the plasma comprises applying an electrical field to a gas which does not contain any oxidizing species.

Statement 13. The method of statement 1 (or any of the statements above), wherein the plasma is flowed from the nozzle exit at a pressure different from an ambient pressure outside the nozzle exit.

Statement 14. The method of statement 1 (or any of the statements above), wherein the plasma is flowed from a converging nozzle having a conical converging section.

Statement 15. The method of statement 1 (or any of the statements above), further comprising:

heating a carrier gas stream with an atmospheric pressure plasma;

injecting cold spray particles into the carrier gas while the carrier gas is directed toward the cleaned surface at supersonic speed; and

coating the activated surface by impingement of the cold spray particles onto the activated surface.

Statement 16. The method of statement 15, wherein coating the activated surface comprises coating the activated surface while the energetic species are still active on the surface at the time of material deposit.

Statement 17. The method of statement 16, wherein coating the activated surface comprises coating the activated surface within 30 minutes of producing the activated surface.

Statement 18. The method of statement 16, wherein coating the activated surface comprises simultaneously cleaning and applying the coating.

Statement 19. The method of statement 18, wherein coating the activated surface comprises applying the coating to a region of the surface where the plasma plume is contacting.

Statement 20. The method of statement 16, wherein coating the activated surface comprises applying the coating to a region of the surface where the plasma plume has been momentarily been moved from.

Statement 21. An atmospheric pressure plasma system configured to operate according to the method of any statements 1-20 (or combinations thereof), the system comprising:

at least one plasma-generating chamber configured to generate a first atmospheric pressure plasma;

a plasma outlet communicating with the plasma-generating chamber;

a plasma plume extending from the plasma outlet into an ambient environment; and

the at least one plasma-generating chamber configured to generate a second atmospheric pressure plasma for preheating a gas stream prior to introduction of precursor particles for a cold spray coating.

Statement 22. The atmospheric pressure plasma system of statement 21, wherein the plasma plume comprises periodic regions of high plasma density and low plasma density exiting the outlet into the ambient environment at supersonic velocity.

Statement 23. The atmospheric pressure plasma system of statement 21 or 22, wherein the plasma outlet is configured for producing pressure waves in the plasma plume.

Statement 24. The atmospheric pressure plasma system of statement 23, wherein the pressure waves are shock waves.

Statement 25. The atmospheric pressure plasma system of statement 21 or 22, further comprising a power source communicating with the electrode and configured for adjusting a drive frequency and a power level applied to the electrode to produce pressure waves in the plasma plume.

Statement 26. The atmospheric pressure plasma system of statement 21 or 22, further comprising a particle injector for injection of the precursor particles into the gas stream.

Statement 27. The atmospheric pressure plasma system of statement 21 or 22, wherein the plasma outlet comprises a converging nozzle having a converging conical section.

Statement 28. The atmospheric pressure plasma system of statement 21 or 22, further comprising a gas supply for supplying a gas to the at least one plasma-generating chamber.

Statement 29. The atmospheric pressure plasma system of statement 28, wherein the gas supply comprises an air supply source configured for supplying air to the at least one plasma-generating chamber.

Statement 30. The atmospheric pressure plasma system of statement 28, wherein the gas supply comprises a helium gas supply source configured for supplying helium to the at least one plasma-generating chamber.

Statement 31. An atmospheric pressure plasma system configured to operate according to any of the method statements 1-20 (or combinations thereof), the system comprising:

a first plasma-generating chamber configured to generate an atmospheric pressure plasma for preheating a plasma-heated gas stream for introduction of precursor particles for a cold spray coating;

a particle injector for injection of the precursor particles into the plasma-heated gas stream; and

a plasma outlet communicating with the first plasma-generating chamber and through which a plasma plume exits into an ambient environment.

Statement 32. The atmospheric pressure plasma system of statement 31, wherein the plasma plume comprises periodic regions of high plasma density and low plasma density exiting the plasma outlet into the ambient environment at supersonic velocity.

Statement 33. The atmospheric pressure plasma system of statement 31 or 32, wherein the plasma outlet is configured for producing pressure waves in the plasma plume.

Statement 34. The atmospheric pressure plasma system of statement 33, wherein the pressure waves are shock waves.

Statement 35. The atmospheric pressure plasma system of statement 31 or 32, further comprising a power source communicating with the electrode and configured for adjusting a drive frequency and a power level applied to the electrode to produce pressure waves in the plasma plume.

Statement 36. The atmospheric pressure plasma system of statement 31 or 32, wherein the plasma outlet comprises a converging nozzle having a converging conical section.

Statement 37. The atmospheric pressure plasma system of statement 31 or 32, further comprising a gas supply for supplying a gas to the first plasma-generating chamber.

Statement 38. The atmospheric pressure plasma system of statement 37, wherein the gas supply comprises an air supply source configured for supplying air to the first plasma-generating chamber.

Statement 39. The atmospheric pressure plasma system of statement 37, wherein the gas supply comprises a helium gas supply source configured for supplying helium to the first plasma-generating chamber.

Statement 40. The atmospheric pressure plasma system of statement 31 or 32, wherein the particle injector for injection of the precursor particles into the plasma-heated gas stream is within the first plasma-generating chamber.

Statement 41. The atmospheric pressure plasma system of statement 31 or 32, wherein the particle injector for injection of the precursor particles into the plasma-heated gas stream is outside of the plasma outlet of the first plasma-generating chamber.

Statement 42. The atmospheric pressure plasma system of statement 31 or 32, wherein the particle injector comprises a second plasma-generating chamber.

Statement 43. The atmospheric pressure plasma system of statement 42, wherein the first plasma generating chamber and the second plasma-generating chamber have respectively a first axis and a second axis that are directed to a common point on a substrate to be treated.

Statement 44. The atmospheric pressure plasma system of statement 42, wherein the first plasma generating chamber and the second plasma-generating chamber have respectively a first axis and a second axis that are directed respectively to a first point and a second point on a substrate to be treated, and wherein the second point is within the plasma plume from the first plasma-generating chamber contacting the substrate.

Statement 45. The atmospheric pressure plasma system of statement 42, wherein the first plasma-generating chamber and the second plasma-generating chamber have respectively a first axis and a second axis that are directed respectively to a first point and a second point on a substrate to be treated, wherein the second point is outside the plasma plume from the first plasma-generating chamber contacting the substrate, and movement of the substrate relative to the first plasma-generating chamber or the second plasma-generating chamber scans the first point and second point on the substrate such that the cold spray coating is applied to a region of the substrate where the plasma plume has been momentarily been moved from.

It will be understood that various aspects or details of the invention may be changed without departing from the scope of the invention. Furthermore, the foregoing description is for the purpose of illustration only, and not for the purpose of limitation—the invention being defined by the claims.

1. A method for cleaning a substrate with atmospheric pressure plasma waves, the method comprising:
generating a plasma at atmospheric pressure, the plasma comprising an energetic species reactive with one or more components of an undesirable material on the substrate;
flowing the plasma from a nozzle exit as a plasma plume exiting into an ambient environment at supersonic velocities; and
exposing the surface of the substrate to the energetic species in the plasma plume, thereby producing an activated surface capable of adhering on contact with a coating material from a cold spray of particles to the activated surface.

2. The method of claim 1, wherein the exposing removes undesirable organic residue from the surface of the substrate or removes undesirable inorganic residue from the surface of the substrate.

3. The method of claim 1, wherein the exposing leaves reactive species on the surface of the substrate.

4. The method of claim 3, wherein the reactive species comprise at least one of OH species, COOH species, carbonyl groups, ether groups, esters, amines, nitrogen species, hydrogen species, and reactive metal species which are not present in the substrate and which promote adhesion between the substrate and the coating material.

5. The method of claim 1, further comprising
applying the coating to the substrate wherein the coating has an adherence to the substrate which passes a mandrel bend test such that, upon bending the substrate with the coating over a cylindrical mandrel prescribed by ASTM D-522, the coating exhibits no delamination; or.
applying the coating to the substrate wherein the coating has an adherence to the substrate which passes an adherence pull test such that, upon adhering the coating to a test pull fixture using procedures of ASTM D4541, the coating exhibits no delamination when pulled at a force prescribed by the ASTM D4541.

6. The method of claim 1, wherein the exposing comprises exposing the surface to the plasma plume such that periodic regions of high plasma density and low plasma density impact the surface of the substrate.

7. The method of claim 1, wherein generating the plasma comprises applying an electrical field to a stream of air, and the energetic species includes an oxidizing-inclusive species, or
wherein generating the plasma comprises applying an electrical field to a gas which does not contain any oxidizing species.

8. The method of claim 1, wherein the plasma is flowed from a converging nozzle having a conical converging section.

9. The method of claim 1, further comprising:
heating a carrier gas stream with an atmospheric pressure plasma;
injecting cold spray particles into the carrier gas while the carrier gas is directed toward the cleaned surface at supersonic speed; and
coating the activated surface by impingement of the cold spray particles onto the activated surface.

10. The method of claim 9, wherein coating the activated surface comprises coating the activated surface while the energetic species are still active on the surface at the time of material deposit.

11. The method of claim 9, wherein coating the activated surface comprises simultaneously cleaning and applying the coating.

12. The method of claim 9, wherein coating the activated surface comprises applying the coating to a region of the surface where the plasma plume has been momentarily been moved from.

13. An atmospheric pressure plasma system configured to operate according to the method of any claims 1-12, the system comprising:
at least one plasma-generating chamber configured to generate a first atmospheric pressure plasma;
a plasma outlet communicating with the plasma-generating chamber;
a plasma plume extending from the plasma outlet into an ambient environment; and
the at least one plasma-generating chamber configured to generate a second atmospheric pressure plasma for preheating a gas stream prior to introduction of precursor particles for a cold spray coating.

14. The atmospheric pressure plasma system of claim 13, further comprising a particle injector for injection of the precursor particles into the gas stream.

15. The atmospheric pressure plasma system of claim 13, wherein the plasma outlet comprises a converging nozzle having a converging conical section.

16. The atmospheric pressure plasma system of claim 21, further comprising a gas supply for supplying a gas to the at least one plasma-generating chamber, and
the gas supply comprises an air supply source configured for supplying air to the at least one plasma-generating chamber.

17. The atmospheric pressure plasma system of claim 21, further comprising a gas supply for supplying a gas to the at least one plasma-generating chamber, and the gas supply comprises a helium gas supply source configured for supplying helium to the at least one plasma-generating chamber.

18. An atmospheric pressure plasma system configured to operate according to any of the method claims 1-12, the system comprising:
a first plasma-generating chamber configured to generate an atmospheric pressure plasma for preheating a plasma-heated gas stream for introduction of precursor particles for a cold spray coating;
a particle injector for injection of the precursor particles into the plasma-heated gas stream; and
a plasma outlet communicating with the first plasma-generating chamber and through which a plasma plume exits into an ambient environment.

19. The atmospheric pressure plasma system of claim 31, wherein the particle injector comprises a second plasma-generating chamber.

20. The atmospheric pressure plasma system of claim 19, wherein the first plasma-generating chamber and the second plasma-generating chamber have respectively a first axis and a second axis that are directed respectively to a first point and a second point on a substrate to be treated,
wherein the second point is outside the plasma plume from the first plasma-generating chamber contacting the substrate, and
movement of the substrate relative to the first plasma-generating chamber or the second plasma-generating chamber scans the first point and second point on the substrate such that the cold spray coating is applied to a region of the substrate where the plasma plume has been momentarily been moved from.
